(19) United States
(12) Patent Application Publication
(10) Pub. No.: US 2017/0082666 A1
(43) Pub. Date: Mar. 23, 2017

(54) DETERMINING ELECTRICAL LOADS

(71) Applicant: FUJITSU LIMITED, Kawasaki-shi (JP)

(72) Inventors: Daisuke MASHIMA, Sunnyvale, CA (US); Mustafa FAISAL, Dallas, TX (US)

(21) Appl. No.: 14/857,714

(22) Filed: Sep. 17, 2015

(51) Int. Cl. G01R 22/06; G01R 22/10; G01R 21/06

(52) U.S. Cl. CPC G01R 22/063; G01R 21/06; G01R 22/10

(57) ABSTRACT

According to some embodiments, the present disclosure may relate to a method that includes receiving an energy consumption trace representing energy usage over time that is sampled at a sampling interval. The method may also include parsing the energy consumption trace into one or more segments using change point detection, and selecting one or more of the one or more segments as a representative always-on load segment based on one or more of the following: a lowest average and a minimum duration. The method may also include determining a periodic always-on load based on the representative always-on load segment and the sampling interval. The present disclosure may also relate to associated systems and devices.

### FIELD

One or more embodiments discussed in the present disclosure are related to determining electrical loads.

### BACKGROUND

Nearly every household in the United States, and even throughout the world utilizes and relies on electrical power. Due to the ubiquitous nature of electrical devices and components, there may always be something on or using power in most households. The devices or components may range from microwave ovens to refrigerators, cellular telephone chargers to televisions, and clothes washers to water heaters, just to name a few examples.

The subject matter claimed in the present disclosure is not limited to embodiments that solve any disadvantages or that operate only in environments such as those described above. Rather, this background is only provided to illustrate one example technology area where some embodiments described in the present disclosure may be practiced.

### SUMMARY

One or more embodiments of the present disclosure may include a method that includes receiving an energy consumption trace representing energy usage over time that is sampled at a sampling interval. The method may also include parsing the energy consumption trace into one or more segments using change point detection, and selecting one or more of the one or more segments as a representative always-on load segment based on one or more of the following: a lowest average and a minimum duration. The method may also include determining a periodic always-on load based on the representative always-on load segment and the sampling interval.

The object and advantages of the embodiments will be realized and achieved at least by the elements, features, and combinations particularly pointed out in the claims.

Both the foregoing general description and the following detailed description provide examples and are explanatory and are not restrictive.

### BRIEF DESCRIPTION OF THE DRAWINGS

Example embodiments will be described and explained with additional specificity and detail through the use of the accompanying drawings in which:

FIG. 1 is a diagram representing an example device configured to determine an electrical load;

FIG. 2A is a diagram representing example system configured to determine an electrical load;

FIG. 2B is a diagram representing another example system configured to determine an electrical load;

FIG. 3A illustrates an example plot of a trace of electrical consumption for an appliance;

FIG. 3B illustrates an example plot of a trace of electrical consumption for an appliance;

FIG. 4A illustrates an example plot of an energy consumption trace of electrical consumption for a household;

FIG. 4B illustrates an example plot of an energy consumption trace of electrical consumption for a household;

FIG. 5 is a diagram representing an example system configured to determine an electrical load in a household;

FIG. 6 is a flowchart illustrating an example method of determining an always-on electrical load;

FIG. 7 is a flowchart also illustrating an example method of determining an always-on electrical load; and

FIGS. 8A and 8B are a flowchart also illustrating an example method of determining an always-on electrical load.

### DESCRIPTION OF EMBODIMENTS

Electricity is a utility with a limited supply. It may be very expensive to generate electricity and there may be a limited capability to store electricity. Therefore, it may be desirable for electricity providers to accurately predict expected electricity consumption. One factor in predicting electricity consumption is the “always-on” load, which may indicate a baseline amount of energy that a household may consume, as described in further detail below. Determining the always-on load for households may thus be advantageous for electricity providers. The always-on load may also be beneficial for household members. For example, when made aware of an always-on load, users in the household may find ways to reduce the always-on load. Reducing the always-on load for a household may benefit the household by reducing an electricity utility bill and may benefit the electricity provider by reducing or eliminating unnecessary electrical usage.

Some embodiments described in the present disclosure may relate to determining an “always-on” electrical load (also referred to as an “always-on load”). In some embodiments, to determine always-on load for either an appliance or a household, an energy consumption trace may be parsed into one or more segments of time using change point detection techniques, the change points designating shifts from one segment to the next segment. The segments may be analyzed to find one or more segments representative of the always-on load. For example, the segment with the lowest average value may be selected as the representative segment, or multiple consecutive segments with the lowest average may be selected. The representative one or more segments may be used to determine the always-on load for a period of time, like a day, a week, a month, etc.

As used in the present disclosure, the terms “always-on electrical load” or “always-on load” may refer to an amount of electricity (e.g., power) that may be drawn from an electricity source and that may be consumed regardless of the existence or absence of user activities. As such, the always-on load may indicate a baseline of energy consumption of an appliance, an aggregate of appliances, or a household. In some embodiments, the always-on load may be based on energy consuming appliances whose operation is agnostic to a user operating the appliance (“user-independent appliances”), or energy consuming appliances whose operations may depend on a user operating the appliance (“user-dependent appliances”).

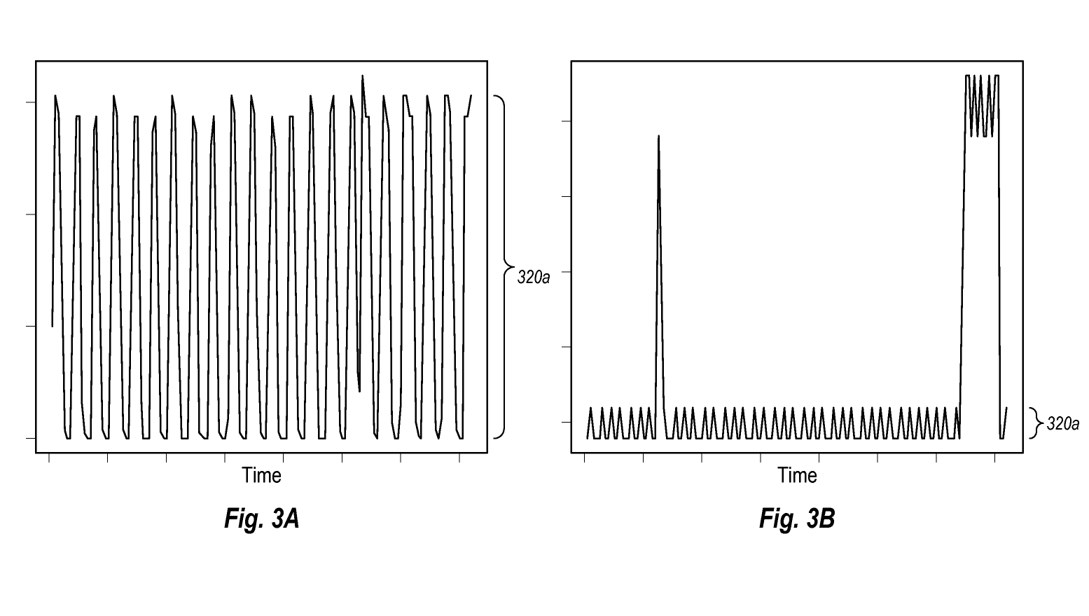

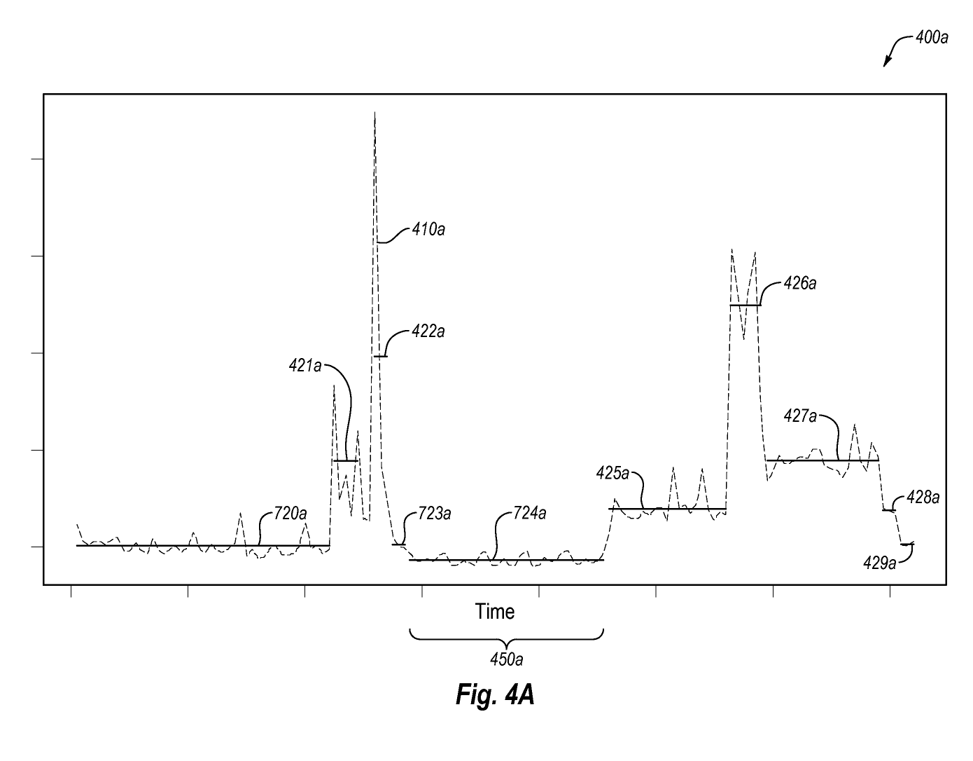

By way of example, for appliances where a user operating the appliance may not actively control the operating state of the appliance, all of the corresponding energy consumption of the appliance may be included in the always-on load. User-independent appliances may include, for example, typical refrigerators or freezers. For example, for a refrigerator without an icemaker, the electricity consumption of the refrigerator may occur when the compressor turns on or off to cool the inside of the refrigerator. The operation of the compressor may occur independently of a user turning on or off the compressor. Such a plot of energy consumption may be observed in FIG. 3A. While there may be certain features of refrigerators that may depend on user interaction with the appliance (e.g. a light turning on when a door is opened or a user turning on an ice maker), the operation of a refrigerator left alone with a door closed serves to illustrate a user-independent appliance.

By way of example, for appliances whose operation state, and consequently power consumption, depend on user activity, only a portion of power consumption may be included in the always-on load. The portion included may be the portion of the consumption that is always present such as an idle state (e.g., stand-by state), while the active state may be excluded. For example, a TV may consume a certain amount of power even when turned off (contributing to the always-on load) and may consume a much larger amount of power when a TV program is watched. Such a plot of energy consumption may be illustrated in FIG. 3B. User-dependent appliances may include, for example; TVs, computers, cable boxes, microwave ovens, or radios. In these and other embodiments, the always-on load of user-dependent appliances may include the energy consumption of the user-dependent appliances when they are idle or in a standby mode.

In some embodiments, the always-on load for a household may not be assumed to be static for each day. While not assumed, the number of energy consuming appliances may typically be static day to day, with occasional changes (for example, when a consumer purchases a new TV or upgrades their heater to a more energy-efficient model). The distinction between user-independent appliances and user-dependent appliances may be described with greater detail with references to FIGS. 3A and 3B.

Embodiments of the present disclosure are explained with reference to the accompanying drawings.

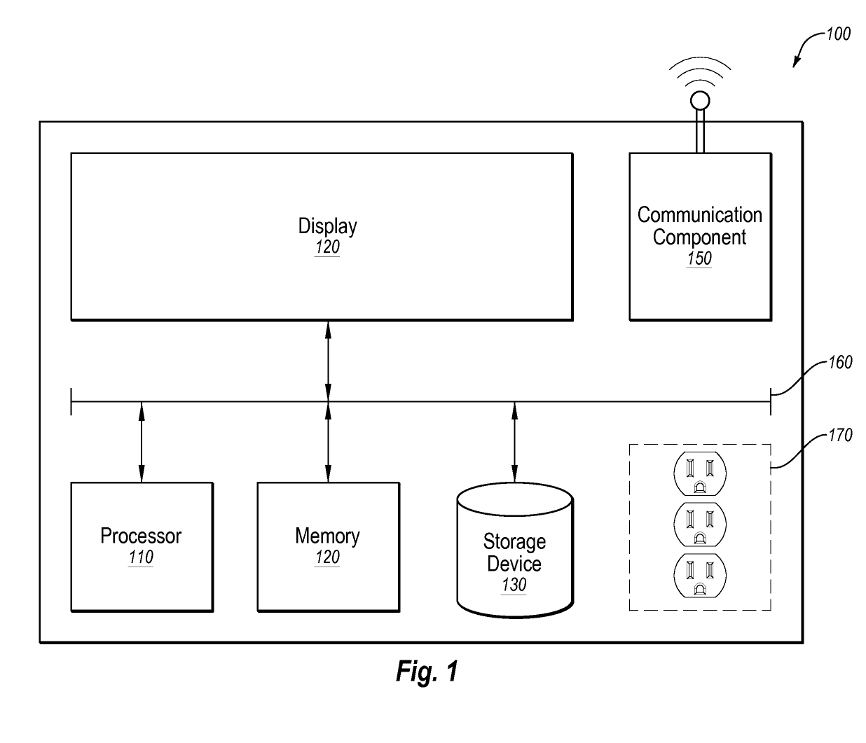

FIG. 1 is a diagram representing an example device 100 configured to determine an electrical load for an appliance or for a household, in accordance with some embodiments of the present disclosure. The device 100 may include a processor 110, a memory 120, a storage device 130, a display 140, a communication component 150, a bus 160, and one or more outlets 170. In operation, the device 100 may determine an energy consumption trace, for example, via the communication component 150 or from the one or more outlets 170. An energy consumption trace may indicate energy usage over time in which the energy consumption of a household or an appliance may be sampled at a sampling interval. For example, the energy consumption traces may include current and/or voltage values at one or more outlets 170 that may be sampled at the outlets periodically. Additionally or alternatively, the energy consumption traces may include power measurements or determinations that may be determined from current and voltage measurements. In these or other embodiments, the energy consumption traces may include time indicators that may indicate times that correspond to the current, voltage, or power values.

In some embodiments, the one or more outlets 170 may periodically (e.g. at a sampling interval) send as a particular energy consumption trace, the electrical consumption (e.g., voltage, current, or power values) through one of the one or more outlets 170 (or all of the one or more outlets 170) to be stored in the memory 120 and/or the storage device 130. Additionally or alternatively, the outlets 170 may also send time stamps that may be associated with samples. The device 100 may correlate the received energy consumption with time (e.g., based on timestamps or known sampling intervals of the outlets 170). By way of another example, a separate household and/or appliance may communicate an energy consumption trace with that may already be correlated with time.

In some embodiments, there may be fewer of the outlets 170 than appliances contributing to the always-on load, or there may be no outlets 170. In these and other embodiments, the device 100 may receive, aggregate, collect, or otherwise generate data for on energy consumption trace for the household. For example, a smart electricity meter for the household may provide an energy consumption trace, for example, from a GREEN BUTTON® service. Additionally or alternatively, the device 100 may receive, aggregate, collect, or otherwise generate data based on a home area network (HAN) device such as a RAINFOREST EAGLET™ device, a home/building energy management system (HEMS/BEMS), etc. Additionally or alternatively, the device 100 may be part of a HAN or HEMS/BEMS.

The device 100 may use the processor 110, the memory 120 and/or the storage device 130 to parse the energy consumption trace into one or more segments using change point detection. The segments may be portions of time in between the change points. The device 100 may use the processor 110, the memory 120 and/or the storage device 130 to analyze the segments and select one or more as representative of an always-on load of the appliance or of the household. The device 100 may display the always-on load via the display 140 and/or may communicate the always-on load via the communication component 150.

The processor 110 may include any suitable special-purpose or general-purpose computer, computing entity, or processing device including various computer hardware or software modules and may be configured to execute instructions stored on any applicable computer-readable storage media, such as the memory 120 and/or the storage device 130. For example, the processor 110 may include a microprocessor, a microcontroller, a digital signal processor (DSP), an application-specific integrated circuit (ASIC), a Field-Programmable Gate Array (FPGA), or any other digital or analog circuitry configured to interpret and/or to execute program instructions and/or to process data. Although illustrated as a single processor in FIG. 1, the processor 110 may include any number of processors configured to perform, individually or collectively, any number of operations described in the present disclosure. Additionally, one or more of the processors may be present on one or more different electronic devices, such as different devices coupled together or communicating remotely.

In some embodiments, the processor 110 may interpret and/or execute program instructions and/or process data stored in the memory 120. In some embodiments, the processor 110 may fetch program instructions from the storage device 130 and load the program instructions in the memory 120. After the program instructions are loaded into memory 120, the processor 110 may execute the program instructions. In some embodiments, the execution of instructions by the processor 110 may direct and/or control the operation of the device 100. For example, the processor 110 may instruct the display 140 to display the always-on load or may instruct the communication component 150 to transmit the always-on load.

In operation, the device 100 may perform any of the operations described below. For example, the device 100 may determine an energy consumption trace, for example, using energy consumption from the one or more outlets or energy consumption communicated via the communication component 150 The device 100 may parse the energy consumption trace into one or more segments of time using change point detection. For example, once the points of change are located, the span of time between the two points may be designated as a segment.

Change point detection may refer to techniques by which the processor 110 may analyze or determine locations in which changes occur in a data set (for example, changes in average or variance exceeding a target threshold). In some embodiments, the threshold for change may be a static value. The static value may be a user selection, a utility provider-wide designation, a default setting, etc. In some embodiments, the target threshold may include a dynamic value. The dynamic value may be determined based on a target number of segments. For example, based on a target number of segments, the processor 110 may select a number of points with maximum change to yield the target number of segments. The maximum change may be any value of change used in change point detection, for example, a maximum change in average or a maximum change in variance. Any change point detection methodology may be used. By way of example, any one of or combination of a binary segmentation method, a PELT algorithm, simple change point methods (e.g. standard normal homogeneity (SNH), nonparametric variants of SNH, two-phase regression, etc.), exact change point detection, coarse grained change point detection, etc. may be used for change point detection.

The processor 110 may analyze the one or more segments to select one or more segments to be representative of the always-on load for an appliance or household. For example, analyzing the one or more segments may include selecting the segment with the lowest average to be representative of the always-on load for the appliance or household. As another example, the processor 110 may determine whether a sampling interval used in the generation of the energy consumption trace exceeds a minimum duration. If not, the processor 110 may group the segments into groups of multiple segments that do exceed the minimum duration. The processor 110 may select the group that has the lowest average value as representative of the always-on load. The processor 110 may also use the representation of the always-on load to extrapolate a periodic always-on load, for example, by multiplying the representative always-on load with a multiple to extend the representation over an entire twenty-four hour period. For example, if a segment was selected as representative of the always-on load for a household and the segment spanned thirty minutes, the representative always-on load may be multiplied by forty-eight to arrive at the periodic always-on load for the household.

In some embodiments, the periodic always-on load may be the always-on load for a twelve hour period, a day (twenty four hours), a week, a month, or any other periodic amount of time.

The memory 120 and the data storage 130 may include computer-readable storage media for carrying or having computer-executable instructions or data structures stored thereon. Such computer-readable storage media may include any available media that may be accessed by a general-purpose or special-purpose computer, such as the processor 110. By way of example, and not limitation, such computer-readable storage media may include tangible or non-transitory computer-readable storage media including RAM, ROM, EEPROM, CD-ROM or other optical disk storage, magnetic disk storage or other magnetic storage devices, flash memory devices (e.g., solid state memory devices), hard disk drives (HDD), solid state drives (SSD), or any other storage medium which may be used to carry or store desired program code in the form of computer-executable instructions or data structures and which may be accessed by a general-purpose or special-purpose computer. The computer-readable storage media may be configured as a stand-alone media or as part of some other system, component, or device. The computer-readable storage media may be configured as a physical media or as a virtualized media. Combinations of any of the above may also be included within the scope of computer-readable storage media. Computer-executable instructions may include, for example, instructions and data configured to cause the processor 110 to perform a certain operation or group of operations.

The display 140 may include any component, device, system, or combination thereof configured to visually depict information. The display 140 may include a cathode ray tube (CRT), a liquid-crystal display (LCD), a thin-film-transistor LCD, a plasma display, one or more light-emitting diodes (LED), one or more organic LEDs, one or more light bulbs, a dot matrix display, a vacuum fluorescent display, a twisted nematic field effect LCD, a super-twisted nematic LCD, electronic paper (e.g. electrophoretic display, electrowetting display, electrofluidic displays, interferometric modulator displays), etc. The display 140 may display information in any format or structure. For example, the display 140 may be implemented as a monitor, screen, panel of lights, etc. The display 140 may be implemented as a stand-alone display or as a sub-part or component of another device or system. The display 140 may include any secondary features such as three-dimensional display, touch-screen control, directional display control (e.g. viewing angle variance for the display 140), etc. Combinations of any of the above may also be included within the scope of the display 140.

The communication component 150 may include any component, device, system, or combination thereof configured to transmit one or more images to another device. The communication component 150 may communicate with other devices at other locations, the same location, or even other components within the same system. The communication component 150 may include, without limitation, a modem, a network card (wireless or wired), an infrared communication device, a wireless communication device (such as an antenna), and/or chipset (such as a Bluetooth device, an 802.6 device (e.g. Metropolitan Area Network (MAN)), a WiFi device, a WiMax device, cellular communication facilities, etc.), and/or the like. The communications component 150 may permit data to be exchanged with a network (such as a cellular network, a WiFi network, a MAN, etc., to name a few examples) and/or any other devices described in the present disclosure, including remote devices.

The bus 160 may include any device, system, component, or collection of components configured to allow or facilitate communication between one or more of the components of the device 100. For example, the bus 160 may allow communication between the processor 110, the memory 120, the storage device 130, the display 140, the communication component 150, and/or the one or more outlets 170. The bus 160 may include, without limitation, multiple parallel wires, a single wire connection between components, a series of slots or ports with electrical connections between them, printed circuits on a circuit board, a daisy-chain connecting components, etc. The bus 160 may be implemented as multiple buses, such as any combination of a control bus, an address bus, a data bus, a system bus, a front-side bus, an internal bus, an external bus, an expansion bus, a peripheral bus, a device bus, a parallel bus, a Peripheral Component Interconnect (PCI) bus, a PCI Express (PCIe) bus, a Small Computer System Interface (SCSI) bus, an Integrated Drive Electronics (IDE) bus, a Serial Advanced Technology Attachment (SATA) bus, an External SATA (eSATA) bus, a FireWire bus, a Universal Serial Bus (USB), etc. The bus 160 may include a controller for directing, regulating, or otherwise controlling flow of data across the bus 160. Such a controller may regulate for artifacts such as cross-talk, timing skew, etc. which may occur on the bus 160.

The outlets 170 may include one or more electrical outlets that include a component or feature to monitor or determine the energy consumption of that outlet. For example, each outlet of the one or more outlets may generate a trace of the amount of electricity consumed by that given outlet by measuring the current that passes through the outlet and/or by measuring the voltage at the outlet. The outlets 170 may provide electricity as any source of electricity, for example, at one hundred twenty Volts (V) and sixty Hertz (Hz) of Alternating Current (AC) to conform to most electricity providers in the United States. As other examples, the outlets 170 may provide the electricity as AC or Direct Current (DC); at one hundred V, one hundred ten V, one hundred fifteen V, one hundred twenty V, one hundred twenty-seven V, two hundred twenty V, two hundred thirty V, or two hundred forty V; fifty Hz or sixty Hz; etc.

In some embodiments, the outlets 170 may be configured to continuously or periodically communicate the energy consumption to one or more components of the device 100, such as the processor 110, the memory 120, the storage 130, the display 140, and/or the communication component 150. The outlets 170 may communicate the energy consumption in the aggregate for all outlets of the outlets 170 that are consuming electricity, or may communicate the energy consumption for each outlet individually. While depicted as being integrated with the device 100, the outlets 170 may be separate components from the device 100 and may be in communication with the device 100 to provide information regarding the energy consumption of the outlets 170. Additionally, while three outlets are depicted, it will be appreciated that any combination of types and number of outlets may be included. For example, there may be dozens, hundreds, thousands, tens of thousands, or millions of outlets communicating with the device 100. In some embodiments, the outlets 170 may be smart outlets, or outlets with some processing capability, which may be used to monitor and/or communicate the energy consumption through the outlets 170. Further, although depicted as being physically included with the device 100, in some embodiments, one or more of the outlets 170 may be physically separate from the device 100 and communicatively coupled to the device 100 to communicate the energy consumption traces for processing by the device 100.

In some embodiments, the device 100 may determine the always-on energy load for a single household, for example, a single electricity customer of a utility company in a single apartment or home. In some embodiments, the device 100 may determine the always-on load for multiple households as a single unit, such as an office building with multiple tenants, a duplex, four-plex, or apartment building, etc. In some embodiments, the device 100 may determine the always-on load for multiple buildings, such as a subdivision, an office park, a region of a city, or an entire city, etc. In some embodiments, the device 100 may determine the always-on load for a single appliance.

Modifications, additions, or omissions may be made to the device 100 without departing from the scope of the present disclosure. For example, in some embodiments, the device 100 may include any number of other components that may not be explicitly illustrated or described. As another example, the device 100, while illustrated as a single device, may be any number of devices or systems communicatively coupled. For example, certain of the tasks performed by the device 100 may be performed by a server, cloud-based service, or any other remote device (e.g. energy consumption trace processing and analysis) and others by a client using a web-browser (display of data), portable device, etc. As yet another example, the device 100 may not have any of the outlets 170.

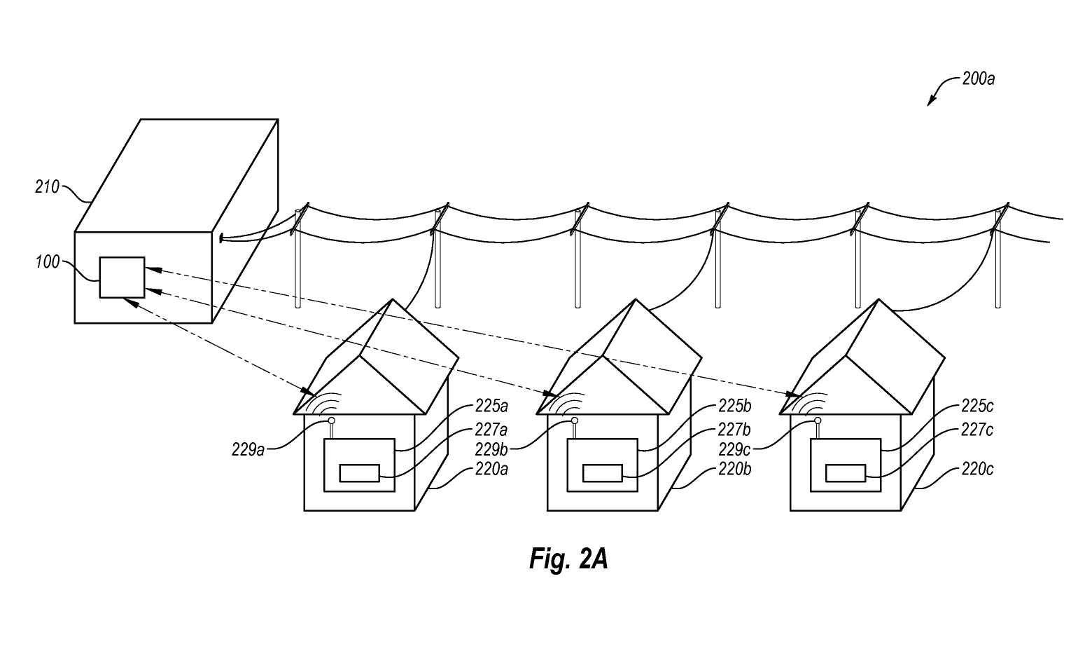

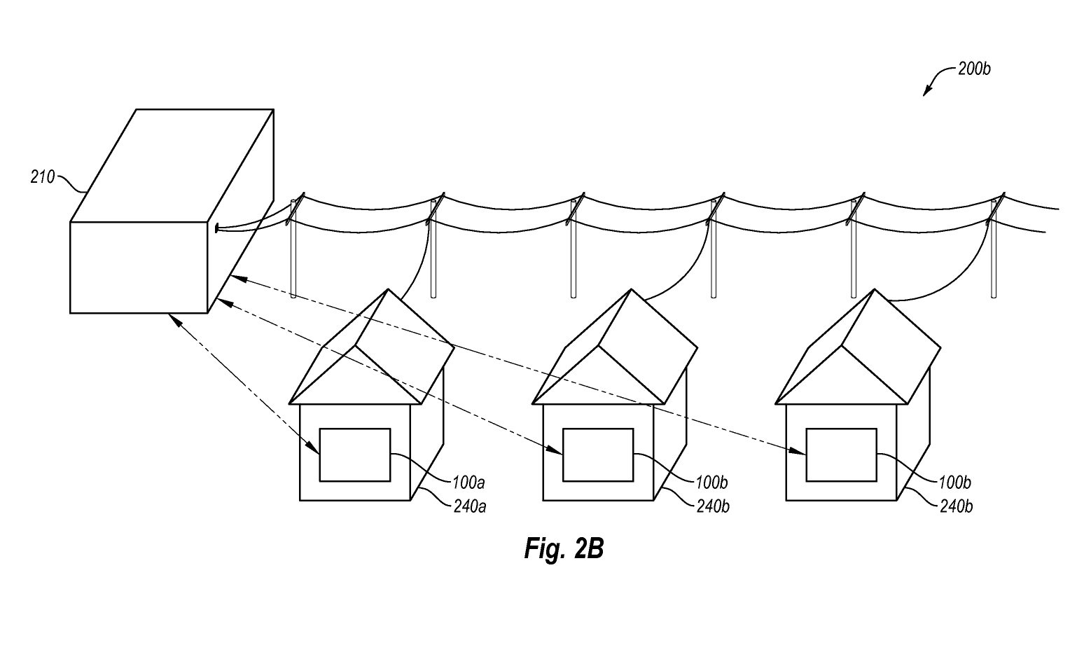

FIGS. 2A and 2B are diagrams representing example systems configured to determine electrical load, in accordance with some embodiments of the present disclosure. FIG. 2A illustrates a system 200a for determining electrical load. The system 200a may include an electricity provider 210 with the device 100. The system 200a may also include one or more households 220a, 220b, and 220c configured to receive electrical power from the electricity provider 210. The one or more households 220a, 220b, and 220c may be in communication with the device 100 of the electricity provider 210. The one or more households 220a, 220b, and 220c may provide the device 100 energy consumption traces associated with the one or more households 220a, 220b, and 220c. The device 100 of the electricity provider 210 may use the energy consumption traces of the one or more households 220a, 220b, and 220c to determine the always-on load of the one or more households 220a, 220b, and 220c. In some embodiments, the device 100 may determine the always-on load for each of the households 220a, 220b, and 220c individually. In some embodiments, the device 100 may determine the always-on load for the households 220a, 220b, and 220c collectively. The device 100 may determine the always-on load in accordance with the present disclosure.

The electricity provider 210 may include any system, utility, organization, entity, company, or combination thereof designed to provide electrical power to one or more consumers of electricity, such as the households 220a, 220b, and 220c. The electricity provider 210 may engage in generation, transmission, distribution, and/or sale of electricity. The electricity provider 210 may include a distribution network to deliver the electricity from the electricity provider 210. The electricity provider 210 may include one or more substations, power lines, transformers, etc. The electricity provider 210 may be in communication with the one or more households 220a, 220b, and 220c. For example, the electricity provider 210 may communicate over the World Wide Web, over Broadband over Power Lines (BPL), or any other communication medium, for example, those described with reference to the communication module 150 of FIG. 1.

The households 220a, 220b, and 220c may include any consumer of electricity provided by the energy provider 210. While illustrated as identical, the households 220a, 220b, and 220c may be implemented as different buildings, units, types of accounts, etc. For example the household 220a may be a single family home, the household 220b may be a large business, and the household 220c may be an apartment complex with many units. The household 220a may include one or more electricity consuming appliances 225a. The household 220a may also include a communication component 229a, which may be implemented the same as the communication component 150 of FIG. 1. The communication component 229a may be part of the one or more electricity consuming appliances 225a.

The household 220a may also include a monitor 227a configured to measure or monitor the energy consumption of the one or more electricity consuming appliances 225a. For example, the monitor 227a may generate a trace of the amount of electricity consumed by the one or more electricity consuming appliances 225a by measuring the current that passes to the one or more electricity consuming appliances 225a. The household 220a may have a single monitor for the entire household, a monitor for each electricity consuming appliance in the household 220a, or multiple monitors for the entire household. In some embodiments, the monitor 227a may send a single energy consumption trace to the device 100 for the energy consumption for the entire household 220a. In some embodiments, the monitor 227a may send multiple traces, one for each of the energy consuming appliances in the household 220a, or some subset of the energy consuming appliances in the household 220a. For example, the monitor 227a may send an energy consumption trace for a set of major energy consuming appliances (e.g. refrigerator, freezer, television, microwave, furnace, etc.) while excluding certain energy consuming appliances (e.g. clock, cellular telephone charger, etc.). In some embodiments, the subset of the energy consuming appliances may be selected based on an absolute value of estimated energy consumption amount (e.g. appliances with a large enough energy consumption may be monitored), a category of appliance (e.g. kitchen appliances vs. small consumer appliances), etc. In some embodiments, the monitor 227a may aggregate multiple energy consumption traces for multiple appliances and send a single energy consumption trace to the device 100.

The household 220b may also include one or more electricity consuming appliances 225b, which may follow the same description of the one or more electricity consuming appliances 225a. The household 220b may also include a communication component 229b, which may follow the same description of the communication component 229a. The household 220b may also include a monitor 227b, which may follow the same description of the monitor 227a.

The household 220c may also include one or more electricity consuming appliances 225c, which may follow the same description of the one or more electricity consuming appliances 225a. The household 220c may also include a communication component 229c, which may follow the same description of the communication component 229a. The household 220c may also include a monitor 227c, which may follow the same description of the monitor 227a.

The electricity provider 210 may use the device 100 to determine the always-on load of the households 220a, 220b, and 220c. For example, the device 100 my parse the energy consumption traces received from the households 220a, 220b, and 220c into one or more segments using change point detection. The device 100 may use the one or more segments to determine a representative always-on load and may use the representative always-on load to determine the periodic always-on load. The device 100 may determine the always-on load on a household-by-household basis, or on a larger scale, such as aggregating the always-on load for multiple households such as the households 220a, 220b, and 220c into a single always-on load.

Modifications, additions, or omissions may be made to the system 200a without departing from the scope of the present disclosure. For example, in some embodiments, the system 200a may include any number of other households, components, etc. that may not be explicitly illustrated or described. For example, there may be thousands or millions of households. As another example, households may have tens, hundreds, or thousands of energy consuming components and/or monitors.

FIG. 2B illustrates an example system 200b for determining electrical load. The system 200b may include an electricity provider 210 in communication with one or more households 240a, 240b, and 240c. The electricity provider 210 may be identical or similar to the electricity provider 210 of FIG. 2A. The one or more households 240a, 240b, and 240c may be implemented similarly to the households 220a, 220b, and 220c of FIG. 2A; however, the households 240a, 240b, and 240c may each include a device 100 of FIG. 1, namely, the devices 100a, 100b, and 100c respectively. In some embodiments, the devices 100a, 100b, and 100c may be in communication with the electricity provider 210.

The devices 100a, 100b, and 100c may operate in a manner similar to that described for the device 100 of FIG. 2A. However, rather than being located at the electricity provider 210, the devices 100a, 100b, and 100c may be located locally at the households 240a, 240b, and 240c. In some embodiments, rather than determining the always-on load for multiple households, the devices 100a, 100b, and 100c may determine the always-on load for the household where they are located, such as the households 240a, 240b, and 240c, respectively. The devices 100a, 100b, and 100c may send the always-on load to the electricity provider 210. The always-on load may be sent as the representative always-on load, or the periodic always-on load.

Modifications, additions, or omissions may be made to the system 200b without departing from the scope of the present disclosure. For example, in some embodiments, the system 200b may include any number of other households, components, etc. that may not be explicitly illustrated or described. For example, there may be thousands or millions of households. As another example, households may have tens, hundreds, or thousands of energy consuming components. In some embodiments, a system in accordance with the present disclosure may be some combination of the systems 200a and 200b. For example, multiple devices 100 may be located at the electricity provider 210. As another example, some households may have devices 100 which may transmit their periodic always-on load to the electricity provider 210 and other households may transmit energy consumption traces to a device 100 of the electricity provider 210 to determine the periodic always-on load for those households without a device 100.

FIGS. 3A and 3B illustrate example plots of traces of energy consumption for two appliances. FIG. 3A illustrates an example appliance that is user-independent and FIG. 3B illustrates an example appliance that is user-dependent. FIG. 3A illustrates a plot 300a of a user-independent appliance, for example, a typical refrigerator. The plot 300a includes a trace 310a of the energy consumption of the refrigerator. When temperatures in the refrigerator increase, the refrigerator turns on to cool the refrigerator, leading to a spike in energy consumption; when the temperature drops below a certain point, the refrigerator turns off, dropping energy consumption. The cyclic spike and drop of the trace 310a is independent of a user operating the refrigerator. For example, there is no control or feature on the refrigerator for the user to turn on a compressor. Instead, the refrigerator automatically may turn on a compressor to cool down the inside of the refrigerator in response to an internal temperature of the refrigerator rising above a certain value. For the trace 310a, the always-on load may include all of the activity, designated by region 320a. While the region 320a is part of the always-on load, the height of the region 320a is not necessarily the always-on load. For example, trace 310a may be averaged over the time duration to determine the always-on load.

FIG. 3B illustrates an example appliance that is user dependent, for example, a typical television. FIG. 3B illustrates a trace 310b of the energy consumption of the television. When the television is not in use, a minimal amount of background electricity is used. However, at certain times of the day (for example to check weather in the morning and then to watch a few shows in the evening), the television is turned on and used more actively, as illustrated by the spikes and areas of relatively high use in electricity. For the trace 310b, the always-on load may include all of the activity designated by region 320b, which may exclude the higher spikes when the television is in use. As with FIG. 2B, the region 320b may not be the actual value of the always-on load, but may indicate the activity contributing to the always-on load.

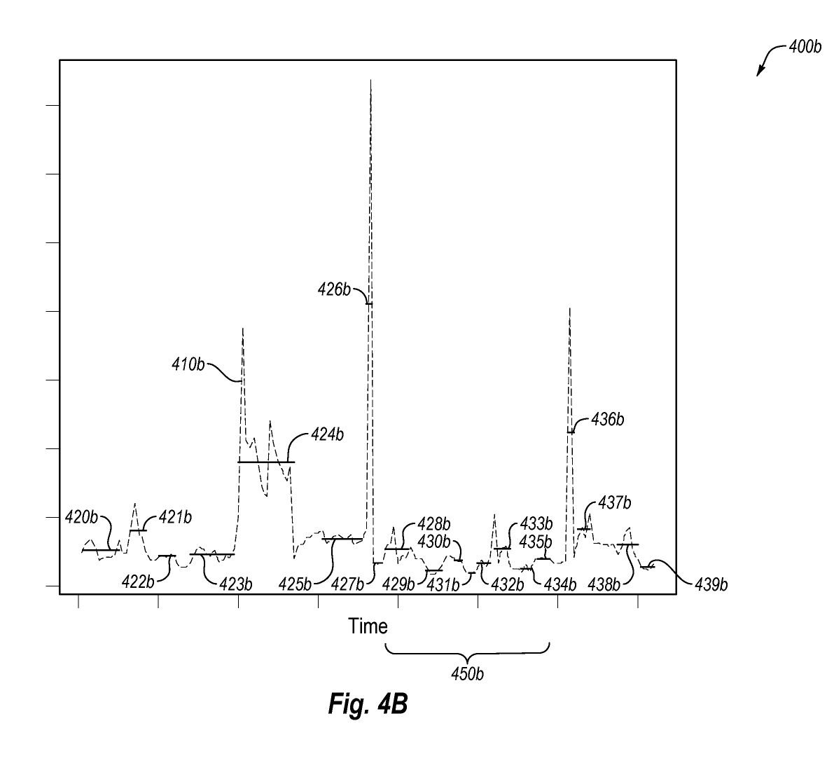

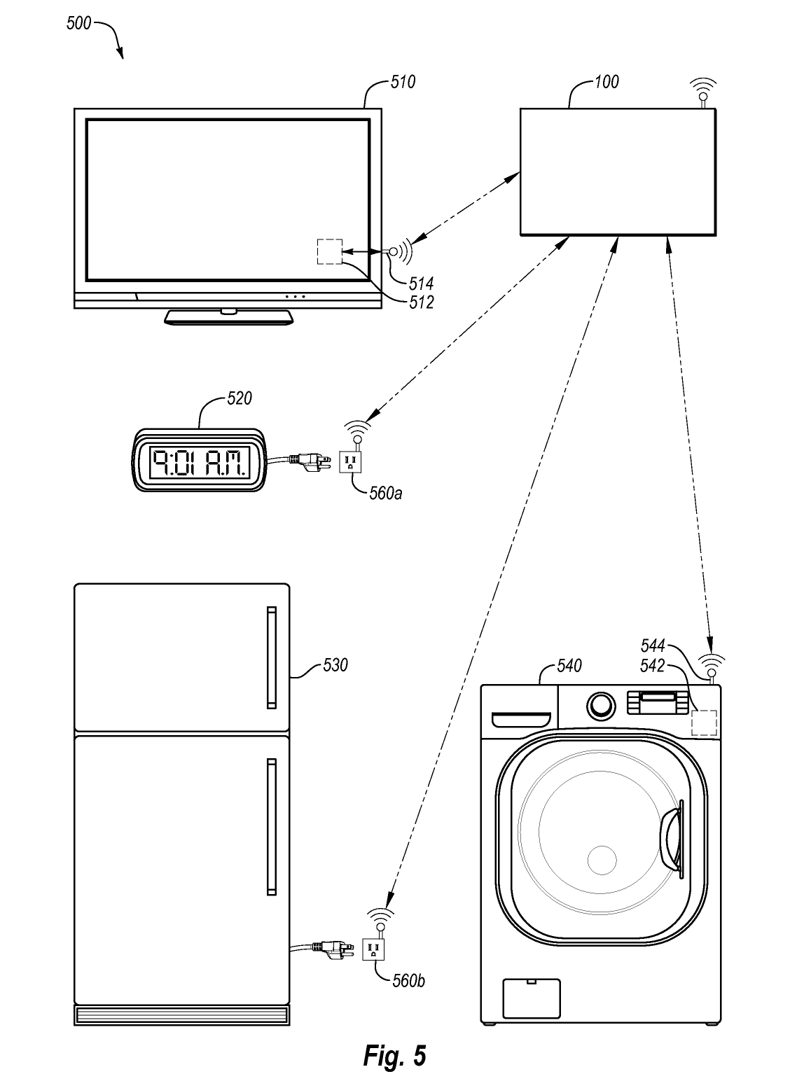

FIGS. 4A and 4B illustrate example plots of traces of electrical consumption for a household, in accordance with some embodiments of the present disclosure. FIG. 4A illustrates a plot 400a including a trace 410a of the energy consumption of a household. The trace 410a may also represent the energy consumption of a particular appliance and the description is as readily applicable to an appliance's energy consumption trace as it is to a household's energy consumption trace. The trace 410a may be parsed using change point detection to separate the trace 410a into multiple segments. For example, a threshold amount of change in variance or change in average may be selected and the trace 410a may be parsed. As another example, a target number of segments may be selected and the trace 410a may be parsed such that the maximum amount of change in variance or change in average may be used while arriving at the target number of segments. Parsing the trace 410a may yield one or more segments, such as the segments 420a, 421a, 422a, 423a, 424a, 425a, 426a, 427a, 428a, and 429a.

The segments of the trace 410a may be analyzed such that a representation of the always-on load may be selected. For example, in some embodiments, the segment with the lowest average value may be selected. With reference to FIG. 4A, for example, the segment 424a may be selected as the segment with the lowest average value, and thus, as the representative always-on load, designated by span 450a. In some embodiments, the segment with the lowest always-on load may be analyzed against a particular time duration, and if the segment does not exceed the duration it may be excluded from being the representative always-on load. Alternatively, the parsing may limit segments to a particular length.

In some embodiments, a determination may be made as to whether the sampling interval for the energy consumption trace is less frequent than a minimum duration. If the sampling interval is more frequent than the minimum duration, the segment with the lowest average value may be selected as the representative always-on load. For example with reference to FIG. 4A, the segment 424a may have the lowest average value of all of the segments of the trace 410a, and so the span 450a may be selected as representative of the always-on load for the trace 410a. In some embodiments, if the sampling occurs frequently enough (e.g. the sample size is large enough) to account for artifacts such as statistical anomalies or outliers, a single segment may be a sufficient metric to utilize as the representation of the always-on load. In some embodiments, sampling may be more infrequent and multiple segments may be selected and averaged as representative of the always-on load. In some embodiments, the minimum sampling frequency may be about thirty minutes, about sixty minutes, etc.

FIG. 4B illustrates a plot 400b including a trace 410b of the energy consumption of a household. The trace 410b may also represent the energy consumption of a particular appliance and the description is as readily applicable to an appliance's energy consumption trace as it is to a household's energy consumption trace. The trace 410b may be parsed using change point detection to separate the trace 410b into multiple segments. For example, a threshold amount of change in variance or change in average may be selected and the trace 410b may be parsed. As another example, a target number of segments may be selected and the trace 410b may be parsed such that the maximum amount of change in variance or change in average may be used while arriving at the target number of segments. Parsing the trace 410b may yield one or more segments, such as the segments 420b, 421b, 422b, 423b, 424b, 425b, 426b, 427b, 428b, 429b, 430b, 431b, 432b, 433b, 434b, 435b, 436b, 437b 438b, and 439b.

The segments of the trace 410b may be analyzed such that a representation of the always-on load may be selected. For example, in some embodiments, multiple segments over a particular time duration may be selected as representative of the always-on load. Multiple segments may be consecutive segments and may have the lowest average value of segments grouped to exceed the particular duration. With reference to FIG. 4B, for example, the segments 429b, 430b, 431b, 432b, 433b, and 435b may be selected and averaged as the segments with the lowest average value over the particular time duration, designated by span 450b.

In some embodiments, a determination may be made as to whether the sampling interval for the energy consumption trace is less frequent than a minimum duration. If the sampling interval meets or is less frequent than the minimum duration, multiple segments may be selected and averaged as the representative of the always-on load. For example with reference to FIG. 4B, if the sampling frequency is less frequent than the minimum duration, the segments 429b, 430b, 431b, 432b, 433b, and 435b may be selected and averaged as representative of the always-on load for the trace 410b.

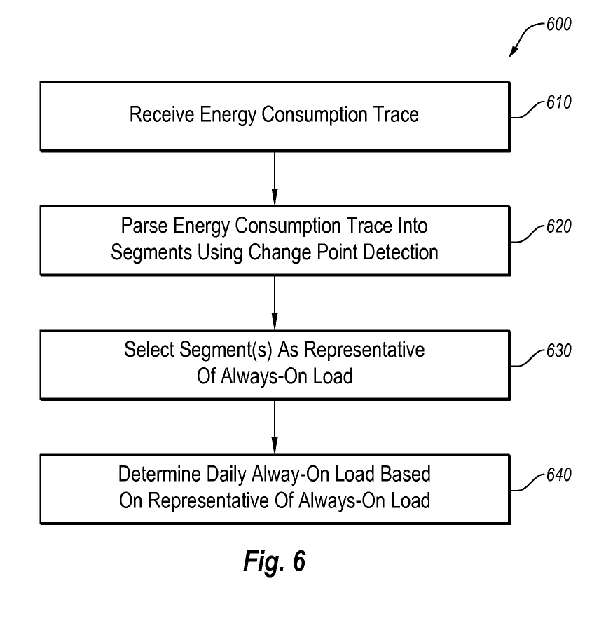

FIG. 5 is a diagram representing an example system 500 configured to determine electrical load in a household, in accordance with some embodiments of the present disclosure. The system 500 may include a device 100 configured to determine the always-on load of a household and/or one or more appliances. The device 100 may be implemented in a similar manner to the device 100 of FIG. 1. The system 500 may also include a set of example appliances: a television 510, a clock 520, a refrigerator 530, and a washing machine 540. Some appliances, such as the television 510, may include a monitor for measuring the energy consumption of the appliance and a communication component 514 for communicating with the device 100. The washing machine 540 is also illustrated as having a monitor 542 and a communication component 544. Some appliances, such as the clock 520 may not be equipped with a monitor. The clock may be plugged in to a stand-alone device, such as a smart outlet 560a including a monitoring component and a communication component, which may perform similar functionality to the monitor 512 and the communication component 514 of the television 510. The refrigerator 530 may also be plugged in to a smart outlet 560b.

In some embodiments, there may be fewer of the outlets 560 than appliances contributing to the always-on load, or there may be no outlets 560. In these and other embodiments, the device 100 may receive, aggregate, collect, or otherwise generate data for on energy consumption trace for the household. For example, a smart electricity meter for the household may provide an energy consumption trace, for example, from a GREEN BUTTON® service. Additionally or alternatively, the device 100 may receive, aggregate, collect, or otherwise generate data based on a home area network (HAN) device such as a RAINFOREST EAGLET™ device, a home/building energy management system (HEMS/BEMS), etc. Additionally or alternatively, the device 100 may be part of a HAN or HEMS/BEMS.

The operation of the device 100 with respect to each of the appliances may be similar. The example operation of the device 100 may be described with respect to the television 510, but the same disclosure is equally applicable to the clock 520, the refrigerator 530, and the washing machine 540. The monitor 512 may measure the electricity usage of the television 510. The communication component 514 may transmit an energy consumption trace of the television 510 to the device 100. For example, the communication component 514 may transmit the energy consumption trace once per day, multiple times per day, once per week, etc. The communication component 514 may continuously send the energy consumption data to the device 100 and the device 100 may generate an energy consumption trace for the television 510. The communication component 514 may periodically send data points of the energy consumption of the television 510 and the device 100 may use those data points to construct the energy consumption trace.

After receipt of an energy consumption trace for the television 510, the device 100 may determine the always-on load for the energy consumption trace, for example, by parsing the energy consumption trace into segments, selecting one or more of the segments as representative of the always-on load of the television 510, and extrapolating the representation into the periodic always-on load. In some embodiments, in selecting the one or more segments as representative of the always-on load, the device 100 may determine whether the segment with the lowest average value is longer than a minimum duration. If it is determined that the segment with the lowest average does exceed the minimum duration, that segment may be selected as representative of the always-on load. If the lowest average value segment is not longer than the minimum duration, the device 100 may determine whether there is another segment that is longer than the minimum duration. If there is such a segment, that segment may be selected as representative of the always-on load. If there is no such segment, the initial segment with the lowest average value may be selected as representative of the always-on load. The minimum duration may be based on the type of appliance, the historical trends of the appliance, published information about an appliance, a default setting, a value set by a user, etc. The minimum duration may also be related to the sampling interval of the energy consumption trace. For example, less frequent sampling intervals may lead to a longer minimum duration of segment length.

The always-on load of the television 510 may be stored and the always-on load for the other appliances may be determined in a similar way. For example, the device 100 may receive energy consumption traces for the clock 520, the refrigerator 530, and the washing machine 540. The device 100 may determine the always-on load for each of the appliances. The device 100 may aggregate all of the always-on load determinations for each of the appliances into a cumulative always-on load for the entire household. In some embodiments, the energy consumption trace and/or the always-on load for a particular appliance may be generated based on published data regarding the appliance, for example, energy usage information provided by ENERGY STAR®, energy guides from the Federal Trade Commission's website, advertised energy consumption by manufacturers, etc.

In some embodiments, the cumulative always-on load determined by aggregating all of the appliances may be compared to an always-on load determination based on an energy consumption trace for the entire household. Based on the comparison, the parsing process for the energy consumption trace of the entire household may be modified such that the always-on load for the entire household comes closer to the always-on load for the aggregated appliances. For example, modifying the parsing process may include changing the number of segments, the threshold amount of change in variance or average observed to set a change point, the change point methodology used, etc. Based on the comparison, the process for determining the periodic always-on load may also be modified. For example, a multiplicative correction factor may be used to correct for over- or under-determining the always-on load using the entire household energy consumption trace as compared to the aggregated periodic always-on load. In some embodiments, any discrepancies between the household always-on load and the aggregated always-on load may be reported to the user via a display, to an electricity provider, etc.

Modifications, additions, or omissions may be made to the system 500 without departing from the scope of the present disclosure. For example, in some embodiments, the system 500 may include any number of other components that may not be explicitly illustrated or described. For example, the system 500 may include any number of appliances and/or smart outlets. As another example, the device 100 may be located locally to the household of appliances, or may be located remotely, for example, at an electricity provider. As another example, the system 500 may include appliances that do not provide their energy consumption to the device 100. As an additional example, the smart outlets 560a and 560b may be part of the device 100 as described with reference to FIG. 1, for example the outlets 170 of FIG. 1.

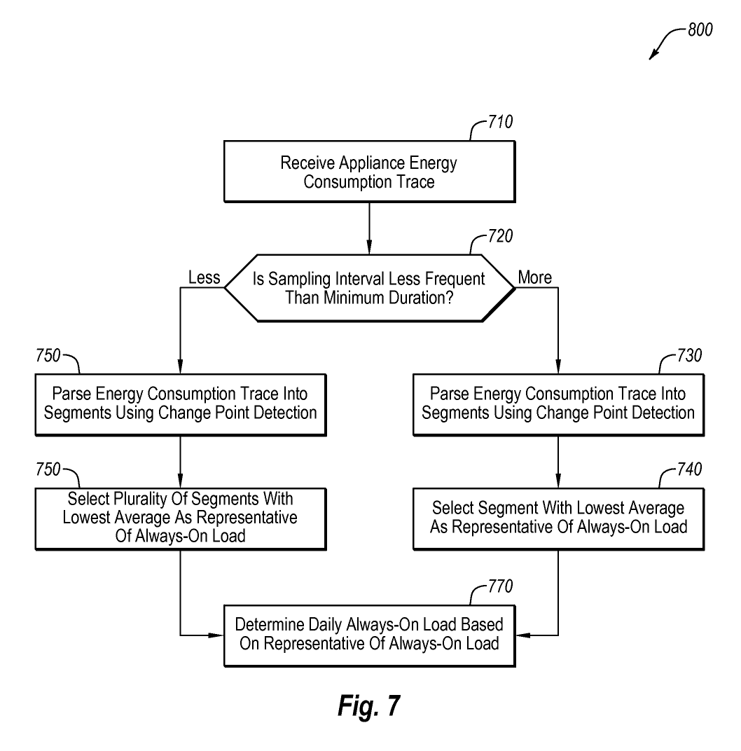

FIG. 6 is a flowchart illustrating an example method 600 of determining always-on electrical load, in accordance with some embodiments of the present disclosure. The method 600 may be performed by any suitable system, apparatus, or device. For example, the device 100 of FIG. 1, the systems 200a or 200b of FIGS. 2A and 2B, or the system 500 of FIG. 5 may perform one or more of the operations associated with the method 600. Although illustrated with discrete blocks, the steps and operations associated with one or more of the blocks of the method 600 may be divided into additional blocks, combined into fewer blocks, or eliminated, depending on the desired implementation.

At block 610, an energy consumption trace may be received. For example, a device such as the device 100 of FIG. 1 may receive an energy consumption trace for a household. The energy consumption trace may be received from a component of the device or may be received from another location.

At block 620, the device may parse the energy consumption trace into one or more segments using change point detection. As described above, parsing the energy consumption trace may include any known change point detection method. In some embodiments, the number of segments may be a specified target number of segments and in some embodiments, the number of segments may be variable depending on the magnitude of change in the energy consumption trace. When a change is detected, the span of time between two detected changes may be designated as a segment.

At block 630, one or more of the segments is selected as representative of the always-on load. Selecting one or more of the segments may include selecting the segment with the lowest average value. Selecting one or more of the segments may also include selecting multiple segments, for example for a certain duration of time, a group of consecutive segments spanning that duration of time and that have the lowest average value for that duration of time compared to other groups of segments may be selected.

At block 640, the periodic always-on load is determined based on the representative always-on load. For example, the representative always-on load may be extrapolated out to a full twenty-four hours based on the sampling interval of the energy consumption trace and the length of the representative always-on load.

Accordingly, the method 600 may be used to determine always-on electrical load. Modifications, additions, or omissions may be made to the method 600 without departing from the scope of the present disclosure. For example, the operations of method 600 may be implemented in differing order. Additionally or alternatively, two or more operations may be performed at the same time. Furthermore, the outlined operations and actions are only provided as examples, and some of the operations and actions may be optional, combined into fewer operations and actions, or expanded into additional operations and actions without detracting from the essence of the disclosed embodiments. All of the examples provided above are non-limiting and merely serve to illustrate the flexibility and breadth of the present disclosure.

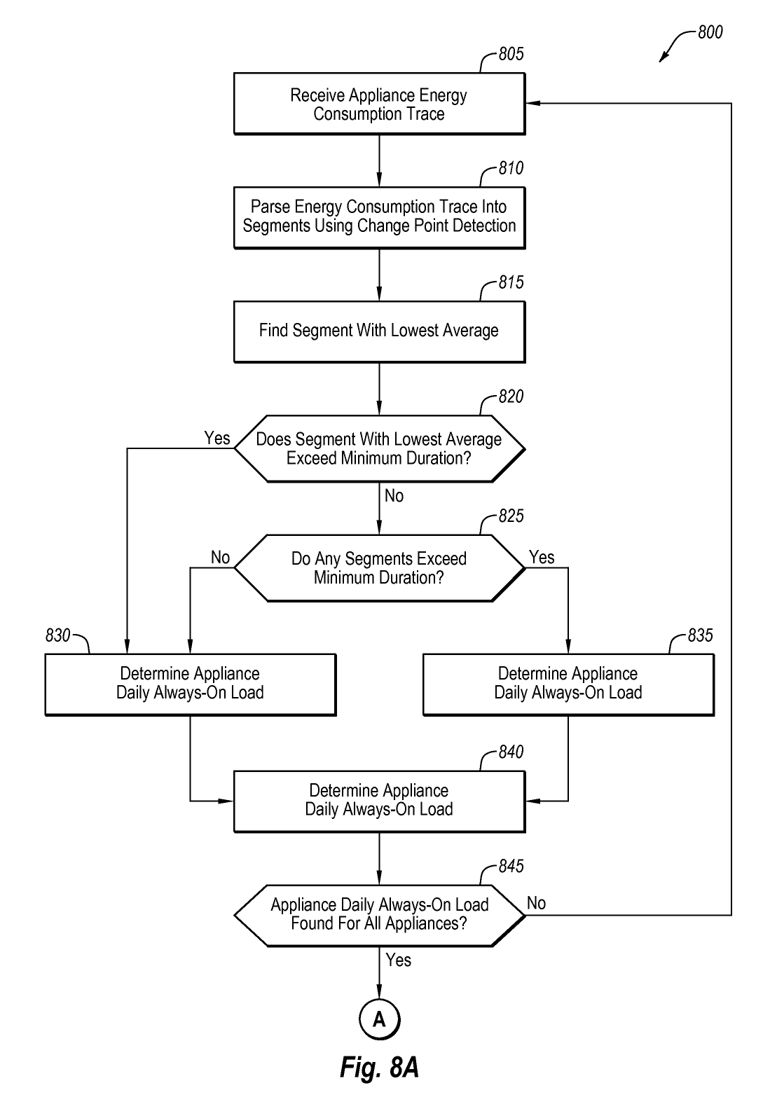

FIG. 7 is a flowchart also illustrating an example method 700 of determining always-on electrical load, in accordance with some embodiments of the present disclosure. The method 700 may be performed by any suitable system, apparatus, or device. For example, the device 100 of FIG. 1, the systems 200a or 200b of FIGS. 2A and 2B, or the system 500 of FIG. 5 may perform one or more of the operations associated with the method 700. Although illustrated with discrete blocks, the steps and operations associated with one or more of the blocks of the method 700 may be divided into additional blocks, combined into fewer blocks, or eliminated, depending on the desired implementation.

At block 710, an energy consumption trace is received. For example, a device such as the device 100 of FIG. 1 may receive an energy consumption trace for a household. The energy consumption trace may be received from a component of the device or may be received from another location. At block 720, the device may determine whether the sampling interval is less frequent than a minimum duration. For example, the device may inquire whether the sampling interval is less frequent than thirty minutes, or in other words, whether each data point in the energy consumption trace is further apart than thirty minutes. The minimum duration may be selected to account for outlier data or other statistical anomalies. After a determination that the sampling interval has occurred more frequently than the minimum duration (for example more frequently than every thirty minutes e.g. every twenty minutes), the method 700 may proceed to block 730. After a determination that the sampling interval has occurred the same as or less frequently than the minimum duration (for example less frequently than every thirty minutes e.g. every forty minutes), the method 700 may proceed to block 750.

At block 730, the energy consumption trace may be parsed into one or more segments using change point detection. In some embodiments, the type of change point detection methodology may be selected based on the more frequent sampling interval. For example, a change point detection mechanism that yields relatively long segments, also referred to as coarse grained segmentation, may be used at block 730. One example approach to doing so may include limiting the number of segments, for example, to ten segments per day, yielding more coarse grained segmentation. At block 740, the segment with the lowest average is selected as representative of the always-on load for the energy consumption trace. The method 700 may then proceed to block 770.

As described above, after a determination that the sampling frequency is the same as or less frequent than the minimum duration, the method 700 may proceed to block 750. At block 750, the energy consumption trace may be parsed into one or more segments using change point detection. In some embodiments, the type of change point detection methodology may be selected based on the less frequent sampling interval. For example, a change point detection mechanism that yields a larger number of smaller segments, also referred to as an exact change point detection method, may be selected due to the less frequent sampling interval.

At block 760, multiple segments may be selected as representative of the always-on load. Selecting multiple segments may include selecting a required duration (for example one hour), and selecting the segment with the lowest average value and determining if that segment is longer than the required duration. If not, segments may be grouped into groups that exceed the required duration and the group of segments with the lowest value may be selected as the representation of the always-on load. In some embodiments, selecting multiple segments may include selecting a predetermined number of segments, for example, based on the sampling interval or the change point methodology used, and selecting the predetermined number of segments to exceed the required duration. The segments may be grouped based on the predetermined number of segments and the group of segments with the lowest average may be selected as representative of the always-on load. The groups of segments may overlap, or in other words, one group may include the first six segments, and the second group may include the second through seventh segments, and the third group may include the third through eighth segments, etc. In some embodiments, multiple segments are consecutive or sequential segments. The method 700 may then proceed to block 770.

At block 770, the periodic always-on load may be determined based on the representative always-on load. For example, the representative always-on load may be extrapolated and/or multiplied to cover an entire twenty-four hours. Such a determination may be based on the sampling interval, the segment length, the representative always-on load, and/or the change point methodology used.

Accordingly, the method 700 may be used to determine always-on electrical load. Modifications, additions, or omissions may be made to the method 700 without departing from the scope of the present disclosure. For example, the operations of the method 700 may be implemented in differing order. Additionally or alternatively, two or more operations may be performed at the same time. Furthermore, the outlined operations and actions are only provided as examples, and some of the operations and actions may be optional, combined into fewer operations and actions, or expanded into additional operations and actions without detracting from the essence of the disclosed embodiments. All of the examples provided above are non-limiting and merely serve to illustrate the flexibility and breadth of the present disclosure.

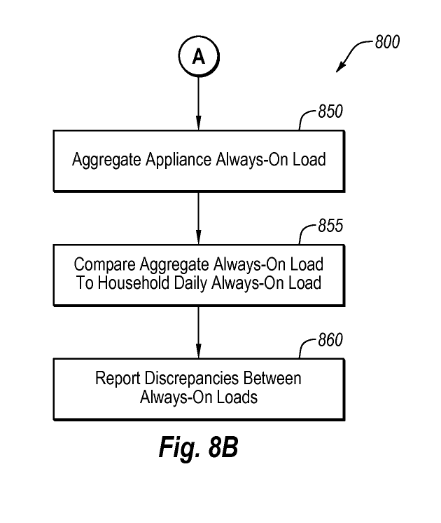

FIGS. 8A and 8B are a flowchart also illustrating an example method 800 for determining always-on electrical load, in accordance with some embodiments of the present disclosure. The flowchart beginning on FIG. 8A continues on to FIG. 8B, and may be thought of as a single figure. The method 800 may be performed by any suitable system, apparatus, or device. For example, the device 100 of FIG. 1, the systems 200a or 200b of FIGS. 2A and 2B, or the system 500 of FIG. 5 may perform one or more of the operations associated with the method 800. Although illustrated with discrete blocks, the steps and operations associated with one or more of the blocks of the method 800 may be divided into additional blocks, combined into fewer blocks, or eliminated, depending on the desired implementation.

In some embodiments, the method 800 may be performed in place of the methods 600 and/or 700 of FIGS. 6 and 7, and in some embodiments, the method 800 may be performed in conjunction with methods 600 and/or 700. For example, in some embodiments the method 800 may be utilized as a verification of the periodic always-on load determined using the methods 600 and/or 700.

At block 805, an appliance energy consumption trace is received. For example, a device such as the device 100 of FIG. 1 may receive an energy consumption trace for an appliance from the appliance or from a smart outlet. At block 810, the appliance energy consumption trace may be parsed into segments using change point detection. As described above, the parsing may use any change point detection methodology, and may include some analysis prior to selecting the change point detection methodology as described with reference to FIG. 7. For example, a determination may be made as to the sampling interval for the appliance energy consumption trace when determining the change point detection methodology and a coarse grained change point methodology may be used for frequent sampling intervals and an exact change point detection methodology may be used for less frequent sampling intervals.

At block 815, the segment with the lowest average may be found. At block 820, a determination may be made as to whether the segment with the lowest average exceeds a minimum duration. For example, a minimum duration of thirty minutes, one hour, or any other value, may be used. The minimum duration of block 820 may be selected to assist in accounting for statistical artifacts or outliers in the energy consumption trace data. If it is determined that the segment with the lowest average value exceeds the minimum duration, the method 800 may proceed to block 830. If it is determined that the segment with the lowest average value does not exceed the minimum duration, the method 800 may proceed to block 825.

At block 825, a determination may be made as to whether any segments exceed the minimum duration of the block 820. If there are no segments that exceed the minimum duration, the method 800 may proceed to block 830. Additionally or alternatively, the block 825 may consider a target number of segments instead of all of the segments (e.g., a number of segments with the lowest averages) and if none of the target number of segments exceeds the minimum duration, the method 800 may proceed to the block 830. If there are segments that exceed the minimum duration, the method 800 may proceed to block 835.

At block 830, the segment with the lowest average value may be used as representative of the always-on load for the appliance. Additionally or alternatively, an average of multiple segments may be taken and used as the representative always-on load for the appliance. For example, if the lowest average segment did not exceed the minimum duration and none of the target number of segments exceeded the minimum duration, the target number of segments may be averaged and used as the representative always-on load. The target number of segments to be used in the average (the block 830) may be different than the target number of segments analyzed to determine whether any segments exceed the minimum duration (the block 825).

At block 835, the segment with the lowest average value that still exceeds the minimum duration of the block 820 may be used as representative of the always-on load for the appliance. The method 800 may proceed to block 840 from both blocks 830 and 835.

At block 840, the appliance periodic always-on load may be determined based on the appliance representative always-on load. For example, the appliance representative always-on load may be extrapolated and/or multiplied to cover an entire twenty-four hours. Such a determination may be based on the sampling interval, the segment length, the appliance representative always-on load, and/or the change point methodology used. The block 840 may also include storing the appliance's periodic always-on load.

At block 845, a determination may be made whether all of the appliances or all of the possible appliances have had their respective periodic always-on loads found or determined. In some embodiments, the block 845 may make the determination based on all of the appliances in a household. In some embodiments, the determination may be made based on a known set of appliances that are able to communicate their own energy consumption or are connected to a smart outlet that may communicate the appliance's energy consumption. In some embodiments, the determination may be made based on a given time window in which one or more appliances may report, and only those appliances that have communicated their energy consumption during that time window may be used. If there are still remaining appliances to have their periodic always-on load determined, the method 800 may proceed to block 805 to begin the process of determining the always-on load for the next appliance. If it is determined at block 845 that all of the appliances or all of the possible appliances have had their periodic always-on loads found, the method may proceed to block 850 (seen in FIG. 8B).

At block 850, the appliance periodic always-on loads for each of the appliances may be aggregated. For example, this may include collecting each of the periodic always-on loads and summing them into a single value. This may also include retrieving the appliances' periodic always-on loads from storage to be aggregated.

At block 855, the aggregated periodic always-on load may be compared to a household periodic always-on load. For example, the household periodic always-on load may be determined as described in methods 600 or 700 of FIGS. 6 and 7 and compared to the aggregated periodic always-on load determined in the method 800, blocks 805 through 850. At block 860, any discrepancies between the aggregated always-on load and the household always-on load may be reported. Such reporting may include displaying any difference on a display of a device like the device 100 of FIG. 1, or may include transmitting any difference to an electricity provider, a provider of smart outlets or appliances, a provider of the device 100, etc.

In some embodiments, any discrepancies may be used to correct the household always-on load. For example, a multiplicative correction factor may be used to correct for over- or under-determining the household always-on load using the entire household energy consumption trace as opposed to the aggregated energy consumption trace based on the appliances of the household. As another example, the change point detection methodology may be changed or modified, including parameters thereof, based on the discrepancy.

Accordingly, the method 800 may be used to determine always-on electrical load. Modifications, additions, or omissions may be made to the method 800 without departing from the scope of the present disclosure. For example, in some embodiments, the blocks 850, 855, and/or 860 may be omitted. As another example, the operations of method 800 may be implemented in differing order. Additionally or alternatively, two or more operations may be performed at the same time. Furthermore, the outlined operations and actions are only provided as examples, and some of the operations and actions may be optional, combined into fewer operations and actions, or expanded into additional operations and actions without detracting from the essence of the disclosed embodiments. All of the examples provided above are non-limiting and merely serve to illustrate the flexibility and breadth of the present disclosure.

As used in the present disclosure, the terms “module” or “component” may refer to specific hardware implementations configured to perform the actions of the module or component and/or software objects or software routines that may be stored on and/or executed by general purpose hardware (e.g., computer-readable media, processing devices, etc.) of the computing system. In some embodiments, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated. In this description, a “computing entity” may be any computing system as previously defined in the present disclosure, or any module or combination of modulates running on a computing system.

Terms used in the present disclosure and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” the term “containing” should be interpreted as “containing, but not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases at least one and one or more to introduce claim recitations. However, the use of such phrases should not be construed to imply that the introduction of a claim recitation by the indefinite articles “a” or an limits any particular claim containing such introduced claim recitation to embodiments containing only one such recitation, even when the same claim includes the introductory phrases one or more or at least one and indefinite articles such as “a” or an (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

All examples and conditional language recited in the present disclosure are intended for pedagogical objects to aid the reader in understanding the disclosure and the concepts contributed by the inventor to furthering the art, and are to be construed as being without limitation to such specifically recited examples and conditions. Although embodiments of the present disclosure have been described in detail, various changes, substitutions, and alterations could be made hereto without departing from the spirit and scope of the present disclosure.

What is claimed is:

1. A method comprising:
receiving an energy consumption trace representing energy usage over time that is sampled at a sampling interval;
parsing the energy consumption trace into one or more segments using change point detection;
selecting one or more of the one or more segments as a representative always-on load segment based on one or more of the following: a lowest average and a minimum duration; and
determining a periodic always-on load based on the representative always-on load segment and the sampling interval.

2. The method of claim 1, wherein parsing the energy consumption trace into one or more segments comprises:
determining a target number of segments; and
parsing the energy consumption trace such that the number of segments is the target number of segments based on a maximum change between adjacent segments.

3. The method of claim 2, wherein selecting one or more of the one or more segments as a representative always-on load segment includes selecting a segment of the target number of segments with the lowest average.

4. The method of claim 1, wherein parsing the energy consumption trace into one or more segments comprises:
determining a minimum threshold of change in one of a variance or an average;
analyzing the energy consumption trace to locate every point in the energy consumption trace that exceeds the minimum threshold of change; and
designating a span of time between the points in the energy consumption trace that exceeds the minimum threshold of change as one of the one or more segments.

5. The method of claim 1, further comprising determining whether the sampling interval is less frequent than the minimum duration;
after a determination that the sampling interval is more frequent than the minimum duration, the selecting one or more of the one or more segments includes selecting the segment with a lowest average value as the representative always-on load segment; or
after a determination that the sampling interval meets or is less frequent than the minimum duration, the selecting the one or more of segments includes averaging a plurality of the one or more segments with a lowest value as the representative always-on load segment.

6. The method of claim 5, wherein the plurality of the one or more segments are consecutive segments.

7. The method of claim 5, wherein a quantity of the plurality of segments is selected based on the duration the plurality of segments.

8. The method of claim 1, further comprising:
receiving an appliance energy consumption trace representing appliance energy usage over time sampled at an appliance sampling interval;
parsing the appliance energy consumption trace into one or more appliance segments using change point detection;
determining whether a first appliance segment with a lowest average exceeds an appliance minimum duration;
after a determination that the first appliance segment with the lowest average exceeds the appliance minimum duration, selecting the segment as an appliance representative always-on load; or
after a determination that the first appliance segment does not exceed the appliance minimum duration:
determining whether any appliance segments exceed the appliance minimum duration;
after a determination that a second appliance segment exceeds the appliance minimum duration, selecting the second appliance segment as the appliance representative always-on load; or
after a determination that no other appliance segments exceed the appliance minimum duration, selecting the first appliance segment as the appliance representative always-on load; and
determining an appliance periodic always-on load based on the appliance representative always-on load and the appliance sampling interval.

9. The method of claim 8, further comprising performing the steps of method 8 for each of a plurality of appliances.

10. The method of claim 9, further comprising:
aggregating the appliance periodic always-on loads for the plurality of appliances;
comparing the aggregation of the appliance periodic always-on loads to the periodic always-on load; and
reporting any discrepancies between the aggregation of the appliance periodic always-on loads to the periodic always-on load.

11. The method of claim 8, wherein the appliance energy consumption trace is generated based on published data regarding an appliance.

12. A non-transitory computer readable medium including instructions that, when executed by a processor, are configured to perform operations, the operations comprising:
receiving an energy consumption trace representing energy usage over time that is sampled at a sampling interval;
parsing the energy consumption trace into one or more segments using change point detection;
selecting one or more of the one or more segments as a representative always-on load segment based on one or more of the following: a lowest average and a minimum duration; and
determining a periodic always-on load based on the representative always-on load segment and the sampling interval.

13. The computer readable medium of claim 12, wherein parsing the energy consumption trace into one or more segments comprises:
determining a target number of segments; and
parsing the energy consumption trace such that the number of segments is the target number of segments based on a maximum change between adjacent segments.

14. The computer readable medium of claim 13, wherein selecting one or more of the one or more segments as a representative always-on load segment includes selecting a segment of the target number of segments with the lowest average.

15. The computer readable medium of claim 12, wherein parsing the energy consumption trace into one or more segments comprises:
determining a minimum threshold of change in one of variance or average;
analyzing the energy consumption trace to locate every point in the energy consumption trace that exceeds the minimum threshold of change; and
designating a span of time between the points in the energy consumption trace that exceeds the minimum threshold of change as one of the one or more segments.

16. The computer readable medium of claim 12, the operations further comprising determining whether the sampling interval is less frequent than the minimum duration;
after a determination that the sampling interval is more frequent than the minimum duration, the selecting one or more of the one or more segments includes selecting the segment with a lowest average value as the representative always-on load segment; or
after a determination that the sampling interval meets or is less frequent than the minimum duration, the selecting the one or more of segments includes averaging a plurality of the one or more segments with a lowest value as the representative always-on load segment.

17. The computer readable medium of claim 12, the operations further comprising:
receiving an appliance energy consumption trace representing appliance energy usage over time sampled at an appliance sampling interval;
parsing the appliance energy consumption trace into one or more appliance segments using change point detection;
determining whether a first appliance segment with a lowest average exceeds an appliance minimum duration;
after a determination that the first appliance segment with the lowest average exceeds the appliance minimum duration, selecting the segment as an appliance representative always-on load; or
after a determination that the first appliance segment does not exceed the appliance minimum duration:
determining whether any appliance segments exceed the appliance minimum duration;
after a determination that a second appliance segment exceeds the appliance minimum duration, selecting the second appliance segment as the appliance representative always-on load; or
after a determination that no other appliance segments exceed the appliance minimum duration, selecting the first appliance segment as the appliance representative always-on load; and
determining an appliance periodic always-on load based on the appliance representative always-on load and the appliance sampling interval.

18. The computer readable medium of claim 17, the operations further comprising:
aggregating the appliance periodic always-on loads for the plurality of appliances;
comparing the aggregation of the appliance periodic always-on loads to the periodic always-on load; and
reporting any discrepancies between the aggregation of the appliance periodic always-on loads to the periodic always-on load.

19. A system comprising:
a plurality of appliances, each appliance having an associated monitor and communication component; and
a device in communication with the plurality of appliances, the device comprising:
a processor; and
a computer-readable medium containing instructions that, when executed by the processor, are configured to perform operations for each of the appliances, the operations comprising:
receiving an energy consumption trace representing energy usage over time that is sampled at a sampling interval;
parsing each of the energy consumption traces into one or more segments using change point detection;
selecting one or more of the one or more segments as a representative always-on load segment based on one or more of the following: a lowest average and a minimum duration; and
determining a periodic always-on load based on the representative always-on load segment and the sampling interval.

20. The system of claim 19, wherein for at least one of the plurality of appliances the associated monitor and the communication component are part of a smart outlet separate from the at least one of the plurality of appliances.
